(19) United States
(12) Patent Application Publication
(10) Pub. No.: US 2012/0186651 A1
(43) Pub. Date: Jul. 26, 2012

(54) APPARATUS, SYSTEMS AND METHODS FOR COLLECTING SOLAR ENERGY

(75) Inventor: William D. Bickmore, Saint George, UT (US)

(73) Assignee: SOLARTRACK, LLC, New York, NY (US)

(21) Appl. No.: 13/357,398

(22) Filed: Jan. 24, 2012

Related U.S. Application Data
(60) Provisional application No. 61/435,868, filed on Jan. 25, 2011.

(51) Int. Cl. H01L 31/0232; H01L 31/18

(52) U.S. Cl. 136/259; 438/69; 257/E31.127

(57) ABSTRACT

Apparatuses and systems for collecting solar energy may include a plurality of holographic optical elements (HOEs) associated with a photovoltaic (PV) cell. Material layers containing HOEs may be attached to directly to a surface of a PV cell or attached to the surface of the module that houses a PV cell. The HOEs alter the angle of incoming sunlight such that the angle of incidence (AOI) of the sunlight on the PV cell is within an accepted angle of acceptance (AOA). In one embodiment one or more material layers have HOEs formed therein and are arranged with respect to the photovoltaic cell such that the plurality of HOEs redirect sunlight along at least one axis when the sunlight is outside a defined AOA and permit sunlight to pass through the at least one material layer without being redirected when the sunlight is within the defined AOA.

### CROSS-REFERENCE TO RELATED APPLICATIONS

This application claims priority to U.S. Provisional Patent Application No. 61/435,868, filed Jan. 25, 2011, entitled A COMPACT PLURALITY OF HOLOGRAPHIC OPTICAL ELEMENTS (HOEs) FOR OPTIMIZING THE PERFORMANCE OF PHOTOVOLTAIC CELLS, the disclosure of which is incorporated by reference herein, in its entirety.

### TECHNICAL FIELD

The present invention relates generally to the collection of solar energy and, more specifically to the use of holograms in collecting solar energy in various apparatuses, systems and methods.

### BACKGROUND

Commercially available photovoltaic (PV) cells are currently believed to be about 5%-20% efficient in their conversion of sun light photon energy into electrical energy under optimal conditions. Suboptimal power generating conditions routinely occur when PVs are used in solar modules which are not perpendicular or normal to the sun's stream of photons.

The optimal output of electrical energy of PV cells is dependent on a variety of factors. For example, the angle of incidence (AOI) of the sun light as it strikes the PV cell has a considerable impact on the electrical output. The electrical load on the PV cell also has an influence on the efficiency of the PV cell. The loss of photon energy due to reflection from the surface of the solar module's protective glass surface has an impact on its efficiency and the resulting electrical output. Certainly the level of energy present in the photons entering the PV is important, as is the ability of the PV cell to convert the energy of the solar spectrum at various wavelengths of light into electrical energy. Many factors relating to the physics of PV cell substrate also have an impact on the efficiency of the system including doping processes and the construction of the solid state diodes formed the PV cell.

Unremarkably, fixed mounted PV module arrays perform sub-optimally throughout most of the power generational day and much of solar year. When the AOI with the suns photon stream nears 90° (i.e., nearly parallel with the plane of the PV cell), the power generation capacity of the PV may be less than 12% of the power generated when the AOI is 0.0°, or at the “normal” angle which, by definition, is 0°. With the sun at 90°, most of the light impinging on the PV cell at this extreme angle is from reflected and scattered atmospheric light.

Various electrical, optical, and mechanical devices have been developed to enhance the capture and absorption of photons in an effort to provide increased efficiency. However, many of such efforts have met with little success and, even if they have worked from a technological standpoint, adoption of the technology is often slow (if adopted at all) due to substantial costs to implement such technology.

For example, a mechanical tracking device may be employed to displace the solar module about one or more axes in an effort to place the PV cell(s) in an orientation such that the AOI is close to perpendicular throughout the day. Trackers may also have a secondary axis which allows tracking of the altitude of the sun's arc which varies seasonally. Referring to FIG. 1, solar arcs are shown representing the sun's position in the sky at different points during the day. Additionally, FIG. 1 shows the solar arcs for different seasons of the year. The solar arc is at its highest at the summer solstice, as shown by a first solar arc 100, and is at its lowest point at the winter solstice as shown by a second solar arc 102. The solar arc is at its mid elevation at both the vernal and autumnal equinoxes as shown at a third solar arc 104.

In an effort to keep a solar module 106 within a desired range of the AOI, a tracking device may be used to move the solar panel relative to its base structure (e.g., a home or other building) about one or more axes. For example, as shown in FIG. 2, a solar module 106 may be coupled to a mechanism 108 that rotates the solar module 106 about a first axis 110 in an effort track the position of the sun throughout the day from one horizon to the other. Additionally, the mechanism 108 may be configured to rotate the solar module 106 about a second axis 112 in an effort to position the solar module relative to the solar arc depending on the season of the year. The mechanism 108 may be controlled by electronics that position the solar panel based on the time of day and on the day of the year. In another embodiment, the tracking mechanism may include a sensor that attempts to track the course of the sun as it traverses the sky.

While a tracking mechanism may help to increase the efficiency of the solar panel by providing a desired AOI for the PV cell, such mechanisms are expensive, add weight and complexity to the overall system, and are often limited due to space available for installation of the system. For example, it is becoming increasingly popular to place solar modules having an array of PV cells on residential rooftops for generation of electricity and conservation of fossil fuels. Mechanical trackers are rarely employed in such applications due to initial cost and the impracticality of installing and maintaining them on a residential roof due to space constraints and structural limitations of the residential roof.

In other attempts to increase the efficiency of a solar module, some solar energy systems employ so-called light concentrator lenses or reflectors in an effort to focus more photons onto the PV cells than they might otherwise capture. While such concentrators and reflectors have proved to have a positive effect in some circumstances, such devices add significant cost to the solar module installation and haven't found wide adoption, particularly in residential applications.

With present payback periods of upwards of 20 years for installation of PV based solar energy systems, the adoption of such technology is slow, at best. State and Federal Governments, as well as utility companies, have offered financial incentives to foster adoption of such systems, but such adoption is still relatively slow.

As such, it is a continual desire of the solar energy industry to improve the performance of solar energy systems. It would be advantageous to provide apparatuses, systems and methods of collecting solar energy that are efficient, that are relatively inexpensive and that are readily adaptable by the solar market, including residential users.

### BRIEF SUMMARY OF THE INVENTION

This invention includes of plurality of holographic optical elements (HOEs) that may be attached to the photovoltaic (PV) cell surface, or attached to the surface of the module that house a PV cell, corrects the angle of incidence (AOI) to a desired angle regardless of the actual angle of incidence as the sun traverses the solar arc daily and as the solar arc elevation varies seasonally. Embedded in the plurality of HOEs are holographic analogs of light redirecting optics which enhance the solar modules intrinsic ability to generate electrical power. The compact plurality of HOEs is designed to reduce the cost of producing electrical energy from PV cells used in a wide variety of applications through an economical increase in efficiency and wherever it is desired to have a smaller footprint of PV solar module arrays.

In accordance with one embodiment, a solar module is provided comprising a photovoltaic cell and at least one material layer being placed above the photovoltaic cell and having a plurality of holographic optical elements (HOEs) formed therein. The at least one material layer and the photovoltaic cell are arranged such that the plurality of HOEs are configured to redirect sunlight along at least one axis when the sunlight is outside a defined angle of acceptance (AOA) and permit sunlight to pass through the at least one material layer without being redirected when the sunlight is within the defined AOA.

In accordance with another embodiment of the present invention, a solar module is provided comprising a frame, a photovoltaic cell coupled with the frame, a layer of glazing material coupled with the frame above the photovoltaic cell, and at least one material layer adhered directly to an external surface of the layer of glazing material. The at least one material layer includes a plurality of holographic optical elements (HOEs) formed therein, wherein the at least one material layer and the photovoltaic cell are arranged such that the plurality of HOEs are configured to redirect sunlight along at least one axis when the sunlight impinges on the at least one material layer at one or more selected angles.

In accordance with another embodiment of the present invention, a method of collecting solar energy is providing. The method includes selecting a solar module having a photovoltaic cell. An angle of acceptance (AOA) for the photovoltaic cell at a target percentage of peak voltage is determined. At least one material layer having a plurality of holographic optical elements (HOEs) is provided and positioned above the photovoltaic cell. Sunlight is redirected by the plurality of HOEs along at least one axis from an angle outside the determined angle of acceptance to a new angle within the determined angle of acceptance.

In accordance with yet another embodiment of the present invention, a method of improving the solar collecting efficiency of an existing solar module is provided. The method includes providing a solar module having a frame, a photovoltaic cell coupled with the frame and a layer of glazing material coupled to the frame and positioned above the photovoltaic cell. At least one material layer having a plurality of holographic optical elements (HOEs) is disposed directly on an external surface of the layer of glazing material.

A variety of other inventive features and aspects of the invention will become apparent upon reading of the detailed description and the claims in conjunction with a review of the drawing figures. The variously described embodiments are not intended to be limiting and features or aspects of one embodiment may be combined with features or aspects of another embodiment without limitation.

### BRIEF DESCRIPTION OF THE SEVERAL VIEWS OF THE DRAWINGS

The foregoing and other advantages of the invention will become apparent upon reading the following detailed description and upon reference to the drawings in which:

FIG. 1 is a diagram showing the solar arc during various seasons;

FIG. 2 is a perspective view of a prior art device;

FIG. 3 is a chart showing angle of acceptance (AOA) data for a PV cell;

FIG. 4 is a chart showing volts produced for various loads for a PV cell;

FIG. 5 is a chart showing watts produces for various loads for a PV cell;

FIG. 6 is a partial cross-sectional view of a solar module;

FIG. 7 is a partial cross-sectional view of a solar module in accordance with an embodiment of the present invention;

FIG. 8 is a partial cross-sectional view of a solar module in accordance with another embodiment of the present invention;

FIG. 9 is a partial cross-sectional view of a solar module in accordance with another embodiment of the present invention; and

FIG. 10 is a schematic of a solar module in accordance with an embodiment of the present invention, showing a solar arc and the change in the path of sunlight before striking an associated PV cell.

### DETAILED DESCRIPTION OF THE INVENTION

Embodiments of the present invention make solar electrical energy more economical by making the solar cells more efficient throughout the solar day and during seasonal elevation changes in the solar arc. Such embodiments provide a less costly alternative to the use of mechanical PV module sun tracking devices.

The ability to convert solar energy into useable energy depends on numerous factors. One of those factors is referred to as the angle of acceptance (AOA) of the sunlight by the photovoltaic (PV) cell. It is estimated that between 80% and 90% of the present world marketplace for PV cells are manufactured from manmade silicon crystalline materials. The angle at which a silicon PV cell can efficiently receive photons and convert their energy into electrical energy is dependent on the electrical load of the PV. When the PV has no load, or in other words, is open circuit or high impedance, the output voltage varies little with the angle of incidence (AOI) of the stream of photons from the sun. At loads which have very low impedance, approaching a short circuit, the angle at which the PV best accepts the energy from a stream of photons is much narrower. It approximates a cosine function with some higher order mathematical variances. When the AOI is at 90°, the photon stream is parallel to the plane of the PV cell. The expected conversion of sunlight into electrical power in terms of Watt-Hours is nearly equal to the cosine of the AOI. At 0°, the cosine is 1.00 and at 90° the cosine is equal to 0.00. The peak Watts of power generation occurs as set forth in Equation 1 (EQ. 1) where Wₚ is the peak Watts, Vₚ is the peak voltage, and R_{L}, is the load resistance in ohms.

EQ. 1

Wₚ=Vₚ²/R_{L}

The maximum efficiency of commercially available PV cells is currently between about 5% and 17%. Because actual solar output varies with atmospheric and other conditions intrinsic to the physics of the sun, 1000 Watts of photon irradiating power per square meter is conventionally used as an industry 100% standard of the solar PV module output. Taking the actual electrical watts output per square meter of a PV cell when exposed to 1000 Watts per square meter of photon energy, dividing that by 1000 and multiplying the result by 100 becomes the “efficiency,” expressed as a percentage, of the PV cell. Where photon irradiance occurs at an AOI of θ=0° (as noted above, 0° being perpendicular or normal to the plan of the PV cell), the cos θ being equal to 1.0 at 0°. Again, the efficiency of the PV cell is greatest with the AOI being 0°.

Specifications of currently available PV cells are conventionally provided at short circuit conditions. Under short circuit conditions, the electrical performance of the PV cell is easily approximated as a pure cosine function of the AOI. However, PV cells do not (and can not) provide power under short circuit conditions. Thus, it becomes important to consider the performance of the PV cell from a different perspective, under load conditions.

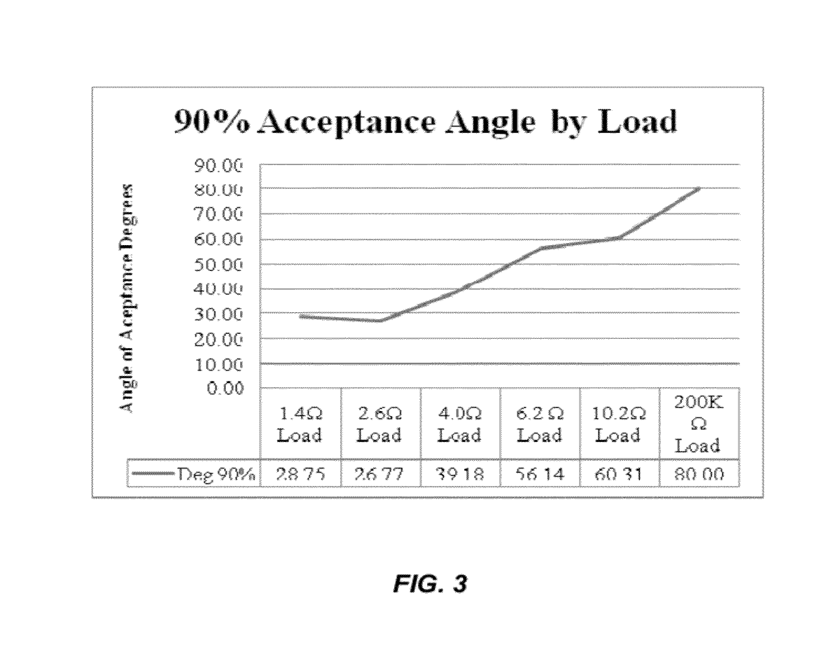

The angle of acceptance (AOA) is the angle at which photons may strike a PV cell at a stated percentage of the PV's maximal operational efficiency. For example, an AOA at 90% is the widest angle at which the PV cell can receive photons with the voltage output of the PV cell not falling below 90% of peak voltage. It is convenient to use the concept of the AOA based on a stated percentage when speaking of variations of output for the PV cell under various load conditions. Referring to FIG. 3, data is shown for a Sharp NE-80EJEA solar module at various loads found for 90% AOA.

Based on the data shown in FIG. 3, a desirable level of the production of power in terms of Watt-hours is found to be at a load of 4.00Ω for this particular solar module. When designing a system of holographic optical elements (HOEs) for the purpose of improving efficiency of a given PV cell, the target percentage associated with the AOA is considered. For example, if one were to set 97% as design target for the AOA, then cos⁻¹(0.97)=14.1°, a relatively narrow angle of acceptance. Considering the data in FIG. 3, under short circuit conditions, the 90% AOA would be cos⁻¹(0.90)=25.8°.

Under the best empirical determined conditions for power generation which meet the manufactures specifications, with the load at 4.0Ω, the 90% AOA is 39.2°. This is obviously a wider angle than the short circuit AOA. Therefore, light entering at an AOI of 39.2° (i.e., at +/− 19.6° relative to the ideal or perpendicular angle), would generate 90% of the electrical energy that the PV cell would have generated had the AOI been at the ideal angle of 0.0° (or directly perpendicular to the plane of the PV cell) with the load at 4.0Ω.

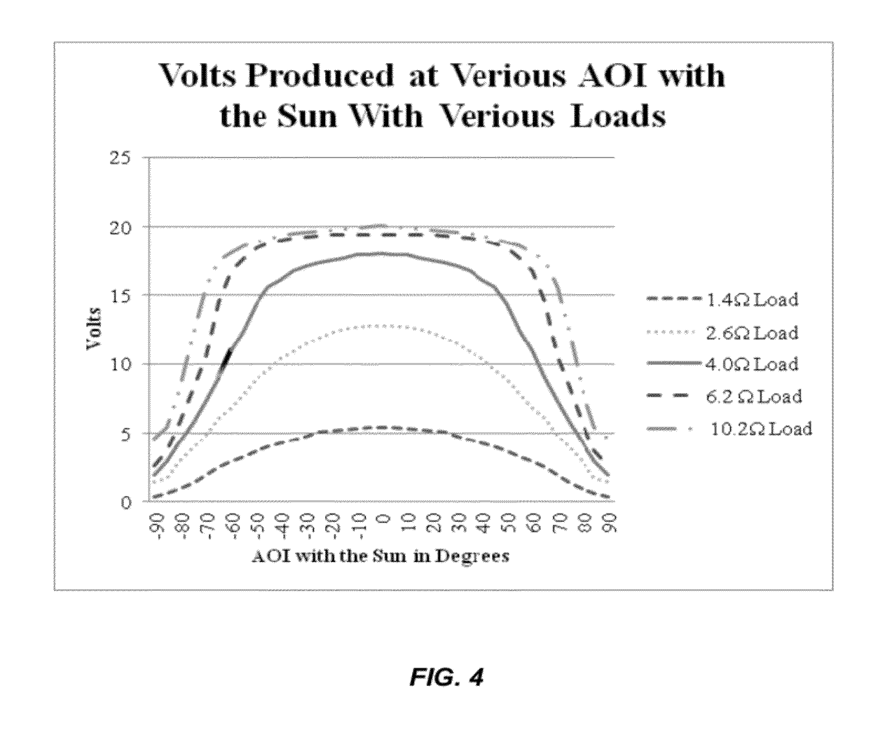

FIG. 4 is a graph showing the voltage produced from the above-referenced PV cell (available from Sharp) at various AOIs and under various load conditions on a bright clear day. The plots were made of the data acquired empirically using resistive loads of 1.4Ω, 2.6Ω, 4.0Ω, 6.4Ω, and 10.2Ω. The results indicate that, contrary to popular thinking, all voltage and power curves do not strictly follow a cosine curve with various AOIs from 0° to 90°. While following a cosine curve tends to be true under short circuit conditions, it is not true when the electrical load is somewhat greater than 0Ω. The voltage curves continue to flatten as the load resistance increases. The measurements represent the various AOIs as sun moves from east to west from sunrise to sunset. Equation 2 (EQ. 2) is empirically derived and closely fits the Sharp solar module with a 4.0Ω load as set forth below.

EQ. 2

Vₒ=(Vₚcosθ)^{X}

Where Vo is the voltage output, Vp is the peak voltage, θ is the AOI, and X is the exponent factor, which in this example for 4.00Ω load is 0.70.

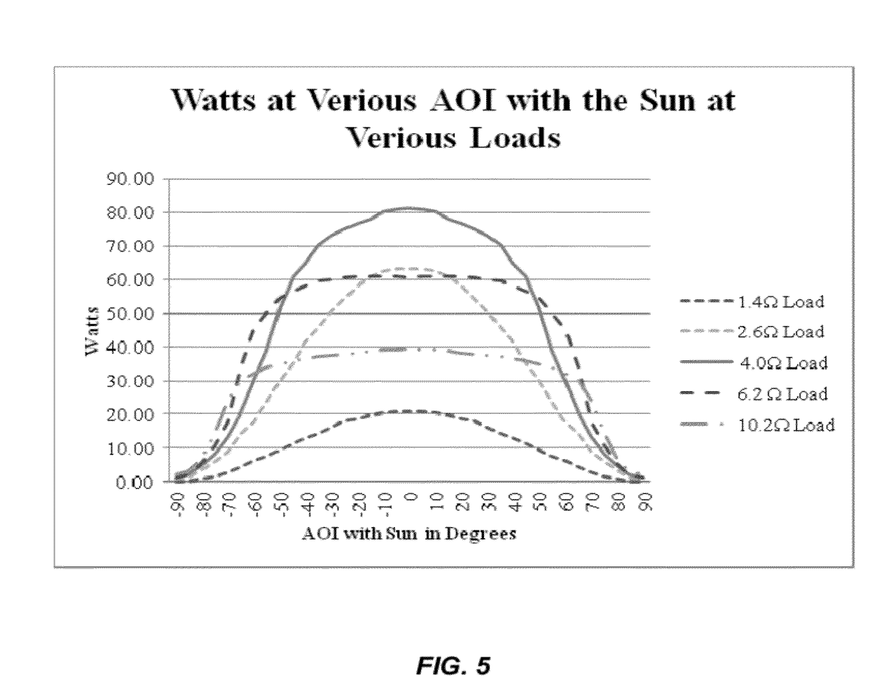

Referring to FIG. 5, a graph showing the wattage associated with the voltage measurements depicted in FIG. 4 is provided, the wattage being calculated using Ohms law, as set forth in Equation 3 (EQ. 3)

W=Vₒ²/R_{L}

Where W is Watts, Vₒ is voltage out and R_{L} is the load resistance.

It is noted that the 4.0Ω load produces the manufacture's specified 80 Watts of power. Other impedances measured, both higher and lower, did not appear to produce the manufacture's rated peak Watts.

The present invention is designed, among other things to replace costly and difficult-to-maintain mechanical tracking systems. A combination of HOEs, including compound HOEs, may be used to enhance the performance and efficiency of photo cells in a multitude of ways. The present invention increases the overall efficiency of the PV cells, reducing the number of solar modules required to produce a given amount of electrical power.

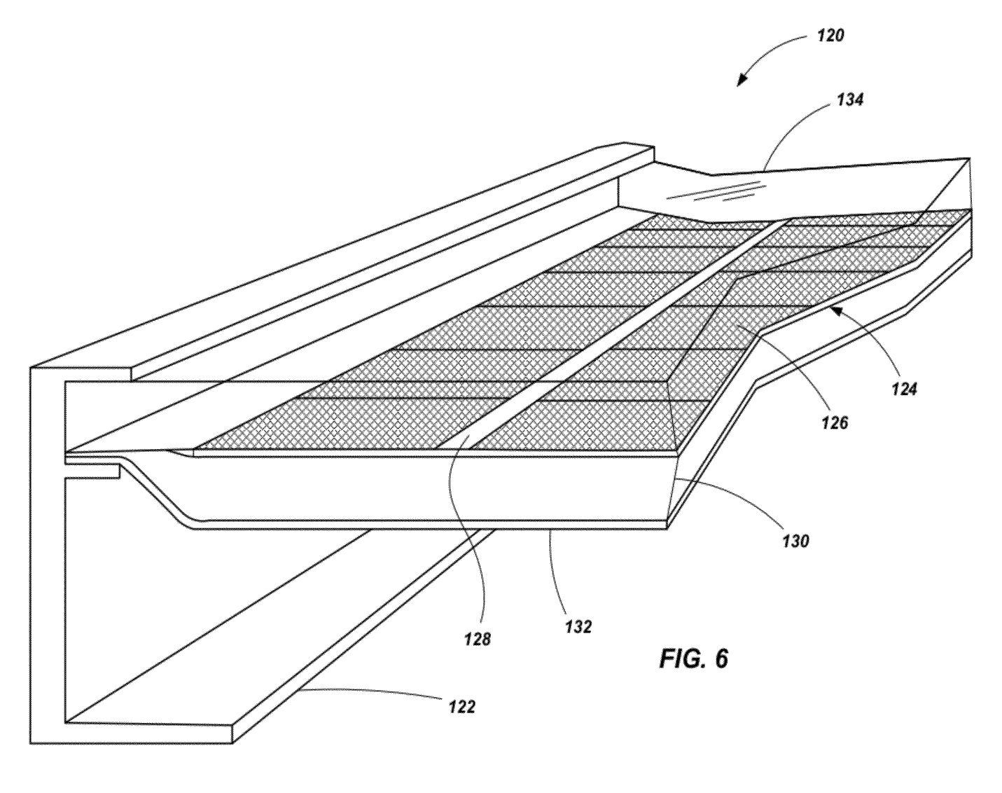

Referring to FIG. 6, a partial cross section of a conventional solar module 120 is shown. The module 120 includes a frame 122 that houses a PV cell 124. The PV cell 124 (which may actually include an array of cells) includes a crystalline photovoltaic 126 that is communication with a bus line 128. The bus line 128 carries electrical energy generated by the crystalline photovoltaic 126 to equipment for conditioning and distribution of the electrical energy. The PV cell 124 may include a variety of features, as will be appreciated by those of ordinary skill in the art, such as an antireflective coating to retain as much of the incident light that strikes the PV cell 124 as possible. A protective layer 130, which may include a polymer material, may be provided to protect the PV cell 124 from shock as well to provide protection from moisture or other environmental influences. A backing material 132 may be bonded to the back of the protective layer 130 to assist in sealing the assembly. A layer of glazing 134 is placed above the PV cell 124 and is coupled with the frame 122. The glazing 134 additionally provides environmental protection to the PV cell 124.

In operation, photons pass through the glazing 134 and are absorbed by the semiconducting materials of the crystalline photovoltaic 126. Negatively charged electrons are then freed from their atoms creating an electric potential. The electric potential produces an electric current along the bus line 128 as a direct current (DC) of electricity.

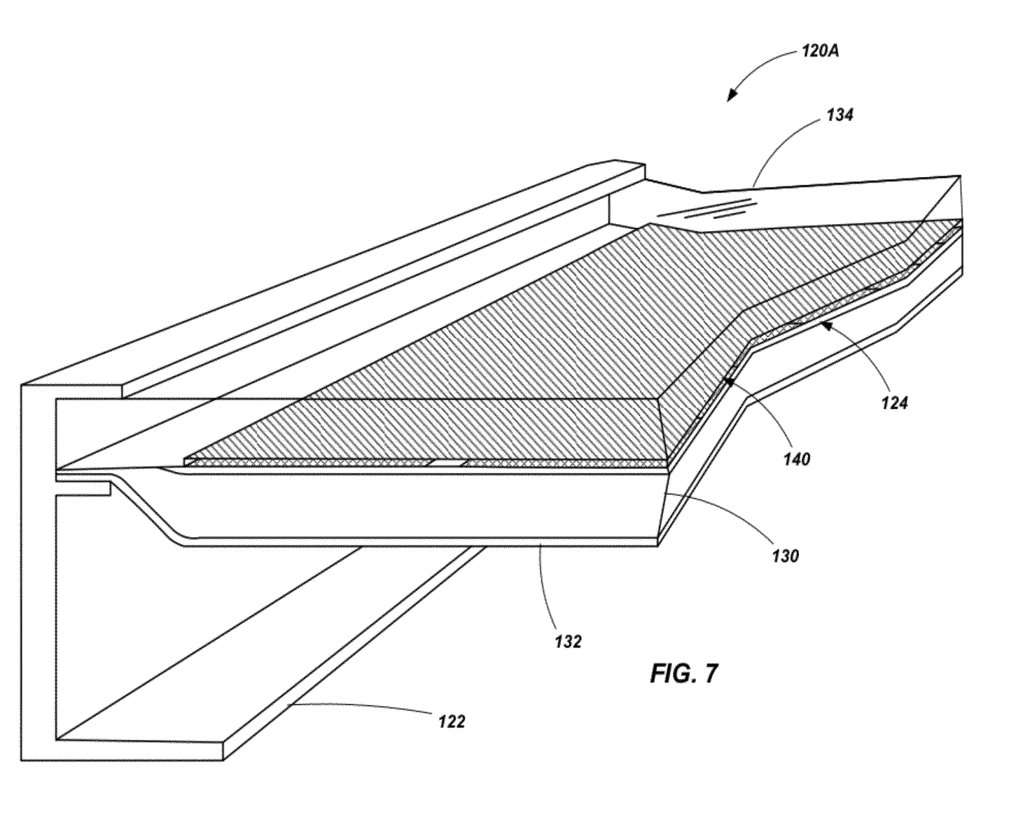

The present invention includes the addition of a plurality of HOEs formed in a thin substrate or film layer. The layer may be as thin as a fraction of a millimeter, which is easily adapted to use in commercial PV modules such as that shown in FIG. 6. The details and design of such an HOE layer will be discussed in further detail below. One embodiment of a solar module 120A that incorporates one or more HOE layers 140 is shown in FIG. 7. The solar module 120A is similar to that which is described in FIG. 4 and includes a frame 122 that houses a PV cell 124. The PV cell 124 includes a crystalline photovoltaic 126 that is communication with a bus line 128. A protective layer 130 and a backing material 132 may provide environmental protection to the PV cell 124. A layer of glazing 134 is placed above the PV cell 124 and coupled with the frame 122. An HOE layer 140 (or a plurality of HOE layers) is sandwiched between the layer of protective glazing 134 and the PV cell 124. The HOE layer 140 is designed and constructed to receive sunlight at a variety of angles and alter the angle such that the AOI on the PV cell 126 is nearly 0°, or at least within a determined AOA.

In one embodiment, the HOE layer only alters the light along a single axis, such as an axis along which the sun traverses throughout the day (i.e., from sunrise horizon to sunset horizon). Thus, the HOE layer 140 enables the sunlight to strike the PV cell 124 at a desired angle, such as within a specified AOA, regardless of where the sun is along its arc from sunrise to sunset.

In another embodiment, the HOEs in the HOE layer may be designed to alter the angle of sunlight along multiple axes. For example, it may be configured to alter the angle of sunlight not only to take into account the position of the sun in its daily arc between sunrise and sunset, but it may also be able to alter the angle of the sunlight as the sun changes position within the sky due to seasonal variations. Again, the angle of the sunlight may be altered to be at substantially ideal angles (i.e., approximately 0°) or within a specified AOA.

In yet a further embodiment, multiple HOE layers 140 may be used with one layer altering the angle of the sunlight along one axis (e.g., to account for the changing position of the sun during a given day) while another layer alters the angle of sunlight along another axis (e.g., to account for the changing seasonal position of the sun).

Referring to FIG. 8, another embodiment of a solar module 120B is shown. The solar module includes a frame 122 that houses a PV cell 124. The PV cell 124 includes a crystalline photovoltaic 126 that is communication with a bus line 128. A protective layer 130 and a backing material 132 may provide environmental protection to the PV cell 124. A layer of glazing 134 is placed above the PV cell 124 and coupled with the frame 122. An HOE layer 140 (or a plurality of HOE layers) is positioned atop of the protective glazing 134 such that the glazing 134 is between the HOE layer 140 and the PV cell 124. The HOE layer 140 may be adhered to the glazing 134 with an appropriate adhesive material. Examples of adhesive may include optically clear adhesives 8171CL and 8172CL available from 3M. Of course other adhesives may be used as well.

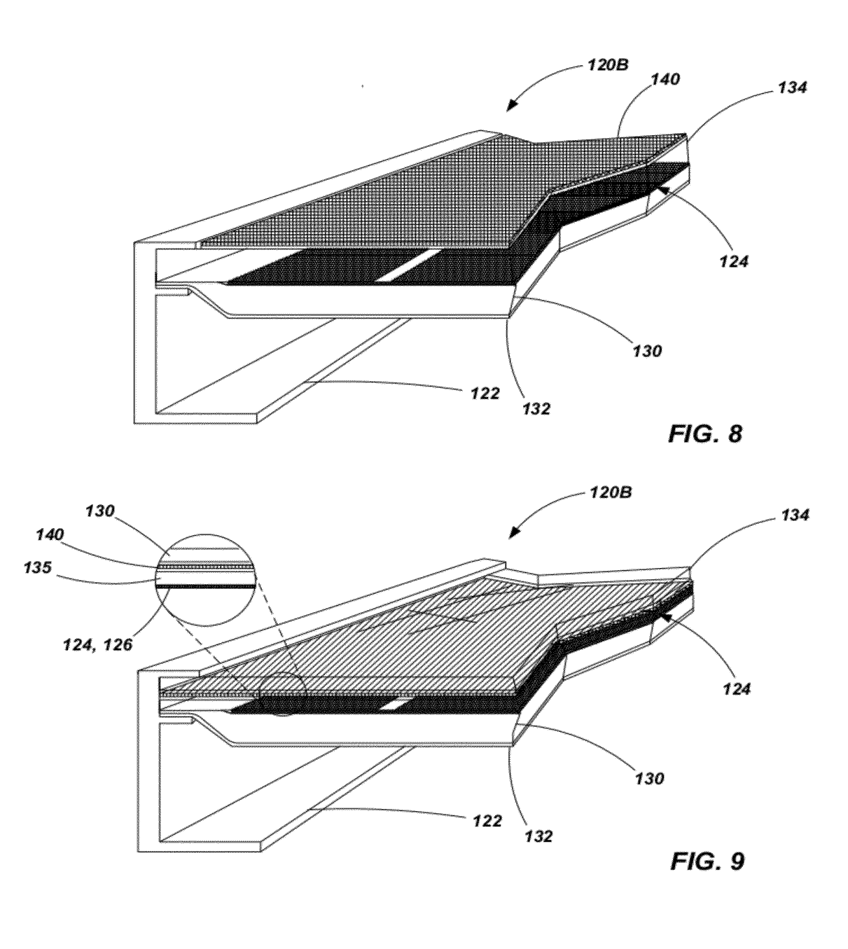

FIG. 9 shows yet another embodiment of a solar module 120C having a frame 122 that houses a PV cell 124. As with previously described solar modules, the PV cell 124 includes a crystalline photovoltaic 126 that is communication with a bus line 128. A protective layer 130 and a backing material 132 may provide environmental protection to the PV cell 124. A layer of glazing 134 is placed above the PV cell 124 and coupled with the frame 122. An HOE layer 140 (or a plurality of HOE layers) may be sandwiched between two layers of glass, such as the layer of protective glazing 134 and another layer of glass 135 positioned directly above the PV cell 124.

In any of the embodiments described herein, even if the HOE layer is sandwiched between two other substrate materials, an adhesive material may be used to secure the HOE layer 140 in position. Use of such adhesive material may provide ease in manufacturing of the solar module as well as provide additional environmental protection to the resulting assembly. In other embodiments, the HOE layers may be held in position by mechanical means.

In some embodiments, the material from which the HOE layer is formed may be selected or designed to act as an antireflective device so as to enable more photons to not be lost through reflection when striking the associated PV cell. Additional materials may be used to further trap photons within the solar module and promote internal reflection if desired, causing initially unabsorbed photons to reflect again and again within a defined space or volume until it eventually strikes the PV cell and is absorbed thereby.

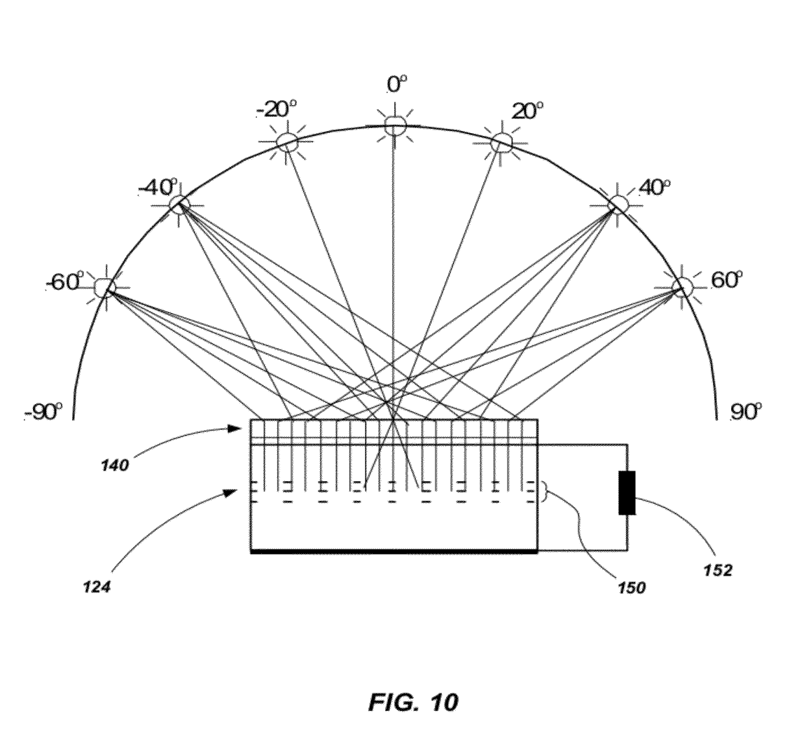

Referring now to FIG. 10, a PV cell 124 is shown with a HOE layer 140 positioned above it. The PV cell 124 includes a photovoltaic 126 having a plurality of P-N junctions 150. A load 152 is applied across the PV cell 124 such as discussed above. The HOEs formed within the HOE layer 140 redirects the sun's rays at more optimal AOI, or at least within an acceptable AOA, using a plurality of internally encoded reflective planes. In one embodiment, the plurality of HOEs redirect the AOI sunlight from sources (or angles) between 20° and 85° and between −20° and −85° in order to compensate for differences in AOI that may occur as the sun traverses the sky during a given day. When the sun is between 20° and −20° during its daily arc, the HOE layer 140 is passive and allows the light to pass through without redirection. Such an HOE layer 140 may be coupled with a PV cell 124 which has, for example, a 90% AOA for 39° (19.5° on each side of the ideal 0° position AOI). Thus, the HOE layer 140 does not redirect the light when the sun is within this range during its daily arc.

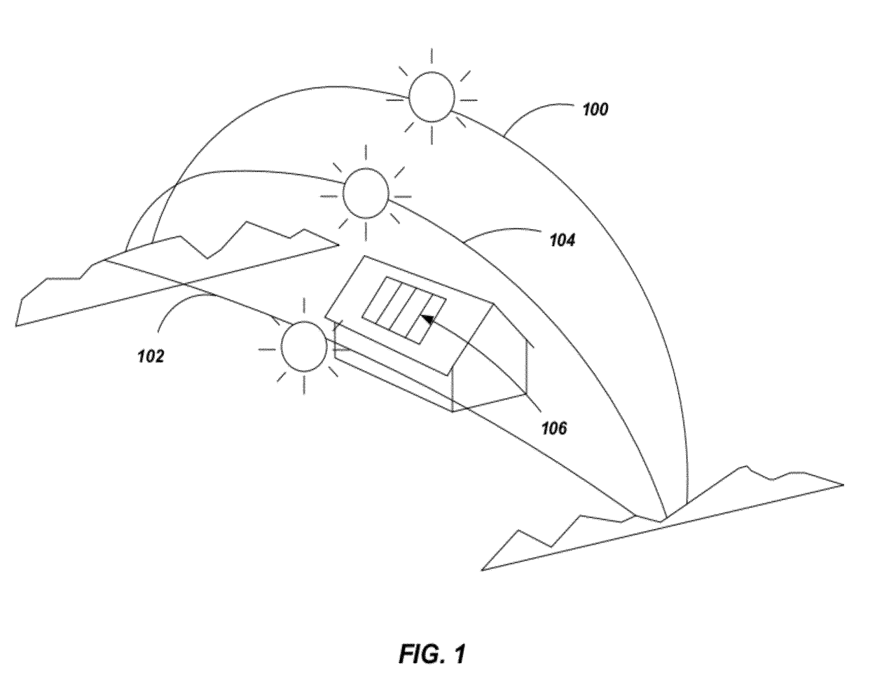

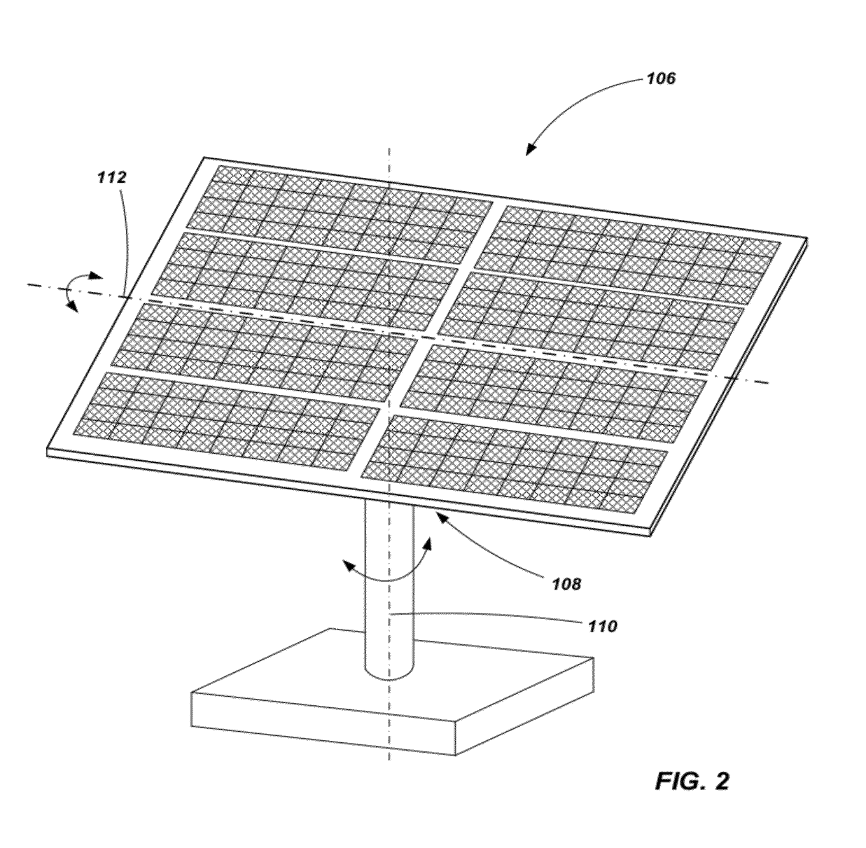

In one embodiment, multiple “types” of holograms may be incorporated into a given assembly. For example, an HOE layer may include at least one “sunrise” hologram that alters the angle of photons when the sun is within a state range of positions on the “sunrise” side of the schematic shown in FIG. 10 (i.e., between −90° and 0°). The HOE layer may also include at least one “sunset” hologram that alters the angle of photons when the sun is within a state range of positions on the “sunset” side of the schematic shown in FIG. 10 (i.e., between −90° and 0°). If desired, the HOE layer may further include at least one “seasonal” hologram to alter the angle of photons due to the sun's seasonal position in the sky (e.g., as indicated in FIG. 1). In one embodiment, these different holograms (sunrise, sunset and seasonal) may be formed in a single layer of material (e.g., a substrate or layer of holographic film). In another embodiment, multiple layers of material may be used, each layer having at least one type of hologram formed therein.

In one particular embodiment, an assembly may be formed having two “sunrise” holograms (or two sets of “sunrise” holograms) and two “sunset” holograms (or two sets of “sunset” holograms). For example, one set of sunrise holograms may be configured to diffract light from an angle within the range of approximately −60° and approximately −40° to a desired AOA (e.g., between approximately −20° and 20°). The second set of sunrise holograms may be configured to diffract light from an angle within the range of approximately −40° and −20° to a desired AOA. Similarly, a first set of sunset holograms may be configured to diffract the sun's light from an angle within the range of approximately 20° to approximately 40° to a desired AOA. The second set of sunset holograms may be configured to diffract the sun's light from an angle between approximately 40° and approximately 60° to a desired AOA. If desired, a seasonal hologram (or seasonal set of holograms) may be configured, for example, to alter the sun's light from an elevation angle between about −20° and about 20° to a desired AOA when, by point of reference, the plane of the PV cell is oriented at 0° at the time of the autumnal equinox and vernal equinox.

In other embodiments, even more holograms (or hologram sets) may be used to cover substantially the entire arc of the sun. For example, numerous “sunrise” holograms may be positioned to account for the sun at different angles between −90° and 0°, with each hologram diffracting the light through an angle that is within the range of approximately 15° to approximately 35° of the solar arc. Additionally, numerous “sunset ” holograms may be positioned to account for the sun at different angles between 0° and 90°, with each hologram diffracting the light through an angle that is within the range of approximately −15° to −35° (when taken in the context of the schematic of FIG. 10). Similarly, numerous seasonal holograms may be used to take into account the entire seasonal shift of the sun within the sky.

The HOEs of a an HOE layer 140 may be designed by using holographic grating design software which takes into account indexes of refraction of various materials, such as a holographic film as well as the silicon substrate of the PV cell. The AOA of a PV cell can be empirically determined. Using Herwig Kogelnic's coupled wave theory, Snell's law, and other optical laws, the HOEs may be designed in a plurality of embodiments suitable for application to any of a variety of existing or newly design solar modules.

In any of the above-described embodiments, the light is redirected by the HOE layer 140 such that the resulting AOI of sunlight is within a favorable AOA of the PV cell. In some embodiments, as previously noted, light trapping features or techniques may also be employed if not already incorporated into physical structures associated with the PV cell. In light trapping, the light may be redirected multiple times (also referred to as internal reflection) until the photons are absorbed by the PV. In one embodiment, light trapping may be accomplished by providing a separate HOE layer with holograms designed and configured to accomplish such light trapping. In another embodiment, such light trapping holograms may be encoded on the same HOE layer that includes holograms that alter the angle of photons to a desired AOI.

In forming an HOE layer, a holographic film must be selected which is suitable for transmission holograms and that has a desired thickness and other physical properties amenable to the creating of HOEs. Either commercially available films or custom formulated films may be utilized. Commercial films, as well as custom films, may be available from providers such as DuPont, Bayer and Holfocus.

In order to provide a product that withstands exposure to the elements, the holographic film utilized may be inherently indifferent to moisture or it may be sealed in the solar module in such a way as to preclude damage to the HOEs by moisture encroachment. In two of the above-described embodiments, the film is protected from moisture by either being hermetically sealed in the solar module along with the PV cell or by being sandwiched between two layers of glass. In the embodiment wherein two layers of glass are used to replace the normal layer of protective glazing, a dichromated gelatin (DCG) film may be used to form the HOE layer along with an ultraviolet curing adhesive commonly known to those familiar with the art.

In another embodiment described above, the HOE layer is located on an external surface of the glazing, outside of any protective enclosure. This embodiment allows for easy retrofitting of existing solar modules by simply adhering, for example, a polymer webbing that includes a plurality of HOEs to the glass or glazing Such an HOE layer may be adhered using a suitable pressure sensitive adhesive (including the examples provided above) from, for example, 3M, Swift or others. Polymer holograms not placed under glass may also need to be protected from ultraviolet light with proper coatings or by an added protective layer of film. Modern forms of holographic film created on polymer web, commonly called plastic film, are available from a variety of sources including, for example, Bayer AG of Germany and DuPont of the USA. Custom or proprietary films may also be developed for use in association with the present invention.

In order to manufacture the various embodiments of the present invention efficient and help them to become readily adapted, the HOE layers may be mass produced in a repeatable process having sufficient quality controls. In one embodiment, a supply or feed stock of holographic film is provided, such as in a roll format. Holographic masters, or mothers, may be prepared (as will be appreciated by those of ordinary skill in the art) which may include custom formulated DCG film on glass. The master is secured in tight contact with a portion of the holographic film. This may be accomplished, for example, through use of a vacuum mechanism or by other mechanical systems.

A suitable laser (or a plurality of lasers) having good coherence and operating at a wavelength suitable for the holographic film's sensitivity are employed. The light of the laser is equally distributed over the entire area upon which the HOEs are to be reproduced. This may be done using beam expander optics, a raster scanner, a flying spot scanner, or by scanning the area with an elongated beam.

After a section of the film is exposed and the image of the master is recoded, the vacuum is released and the film advances. The exposed film may be collected in a take-up real or a set of buffer rollers which can accommodate variations in speed between the exposure unit (also known as a camera) and any post exposure processing systems.

Post exposure processing may vary considerably depending on the film type and the manufacturer of a give film. The simplest post processing may only require exposure to UV light. Other post processes may require the film to pass through as series of properly controlled chemical baths.

Once the holographic film has been exposed and processed, the finished roll may be fed through a laminating device that places a thin pressure sensitive adhesive layer and a removable protective paper covering for the adhesives on one side of the film. Various quality assurance checks may be conducted during and after the manufacturing process.

The finished film may be cut into sections which may be as small as 6 inches×6 inches, the current standard size of single PV cells in the industry, or it may be cut into various sizes to match the typical sizes for solar modules (which include an array of PV cells). Such cut sheets may be, for example, from 1 to 2 feet in width, and from 2 to 4 feet in length. In other embodiments, the film may be cut into a desired width and rolled for subsequent custom sizing during application of the HOE layer to a solar module. Thus, the film containing the HOEs may be sent into the field in roll form and cut into the appropriate sizes by a customer/installer. For example, once in the customer's hands, the exposed and processed roll-stock can be cut to length by commonly available equipment in the marketplace. Customers with automated lines may choose to automate the application of the holograms to either the PV cell or to the PV module such as in accordance with embodiments described above. In the field, teams of retrofitters may cut an apply cut sections of roll stock to the faces of previously installed solar modules.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention includes all modifications, equivalents, and alternatives falling within the spirit and scope of the invention as defined by the following appended claims.

What is claimed is:

1. A solar module comprising:
a photovoltaic cell; and
at least one material layer being placed above the photovoltaic cell and having a plurality of holographic optical elements (HOEs) formed therein, wherein the at least one material layer and the photovoltaic cell are arranged such that the plurality of HOEs are configured to redirect sunlight along at least one axis when the sunlight is outside a defined angle of acceptance (AOA) and permit sunlight to pass through the at least one material layer without being redirected when the sunlight is within the defined AOA.

2. The solar module of claim 1, wherein the plurality HOEs is configured to redirect the sunlight to an angle of incidence (AOI) that is substantially perpendicular to a plane of the photovoltaic cell.

3. The solar module of claim 1, wherein the plurality HOEs is configured to redirect the sunlight to an angle of incidence (AOI) relative to a plane of the photovoltaic cell that is within the defined AOA.

4. The solar module of claim 1, wherein the defined AOA is approximately 40°.

5. The solar module of claim 4, wherein a plane of the solar cell is perpendicular to an angle defined as 0°, and wherein the plurality of HOEs are configured to redirect sunlight impinging on the at least one material layer at angles of or between approximately −20° and −85° and angles of or between approximately 20° and 85° relative to the defined 0° angle.

6. The solar module of claim 1, wherein the plurality of HOEs are configured to redirect light along at least two different axes.

7. The solar module of claim 1, wherein the at least one material layer includes a first material layer having a first plurality of HOEs configured to redirect light along a first axis and a second material layer have a second plurality of HOEs configured to redirect light along a second axis.

8. The solar module of claim 7, wherein the first plurality of HOEs redirect light as the sun extends from its sunrise horizon to its sunset horizon and wherein the second plurality of HOEs redirect light as the sun changes its seasonal position in the sky.

9. The solar module of claim 1, wherein the at least one material layer is coupled directly to an upper surface of the photovoltaic cell.

10. The solar module of claim 1, wherein the at least one material layer is disposed between the photovoltaic cell and a layer of glazing material.

11. The solar module of claim 1, further comprising a layer of glazing material disposed above the photovoltaic cell, and wherein the at least one material layer is disposed directly on an external surface of the layer of glazing material.

12. The solar module of claim 11, wherein the at least one material layer is adhered to the layer of glazing material with an adhesive material.

13. The solar module of claim 11, further comprising an ultraviolet protective film positioned over the at least one material layer.

14. The solar module of claim 1, wherein the at least one material layer comprises a polymer holographic film

15. A solar module comprising:
a frame;
a photovoltaic cell coupled with the frame;
a layer of glazing material coupled with the frame above the photovoltaic cell; and
at least one material layer adhered directly to an external surface of the layer of glazing material, the at least one material layer comprising a plurality of holographic optical elements (HOEs) formed therein, wherein the at least one material layer and the photovoltaic cell are arranged such that the plurality of HOEs are configured to redirect sunlight along at least one axis when the sunlight impinges on the at least one material layer at one or more selected angles.

16. The solar module of claim 15, wherein the plurality of HOEs are configured to redirect the sunlight to an angle within a defined angle of acceptance as it impinges on the photovoltaic cell.

17. The solar module of claim 15, wherein plurality of HOEs are configured to redirect sunlight along multiple axes.

18. The solar module of claim 15, wherein the at least one material layer includes a first material layer having a first plurality of HOEs configured to redirect light along a first axis and a second material layer have a second plurality of HOEs configured to redirect light along a second axis.

19. The solar module of claim 18, wherein the first plurality of HOEs redirect light as the sun extends from its sunrise horizon to its sunset horizon and wherein the second plurality of HOEs redirect light as the sun changes its seasonal position in the sky.

20. A method of collecting solar energy, the method comprising:
selecting a solar module having a photovoltaic cell;
determining an angle of acceptance (AOA) for the photovoltaic cell at a target percentage of peak voltage;
providing at least one material layer having a plurality of holographic optical elements (HOEs);
positioning the at least one material layer above the photovoltaic cell; and
redirecting sunlight by the plurality of HOEs along at least one axis from an angle outside the determined angle of acceptance to a new angle within the determined angle of acceptance.

21. The method according to claim 20, wherein providing at least one material layer having a plurality of holographic optical elements (HOEs) includes providing a first material layer having a first plurality of HOEs that redirect light along a first axis and providing a second material layer having a plurality of HOEs that redirect light along a second axis.

22. The method according to claim 20, wherein providing a solar module includes providing a solar module having a layer of glazing material disposed above the photovoltaic cell, and wherein providing at least one material layer having a plurality of holographic optical elements (HOEs) includes adhering the at least one material layer directly to an external surface of the layer of glazing material.

23. The method according to claim 20, wherein providing a solar module includes providing a solar module having a layer of glazing material disposed above the photovoltaic cell, and wherein providing at least one material layer having a plurality of holographic optical elements (HOEs) includes disposing the at least one material layer between the layer of glazing material and the photovoltaic cell.

24. A method of improving the solar collecting efficiency of an existing solar module, the method comprising:
providing a solar module having a frame, a photovoltaic cell coupled with the frame and a layer of glazing material coupled to the frame and positioned above the photovoltaic cell;
disposing at least one material layer having a plurality of holographic optical elements (HOEs) directly on an external surface of the layer of glazing material.

25. The method of claim 24, wherein disposing at least one material layer having a plurality of holographic optical elements (HOEs) directly on an external surface of the layer of glazing material includes adhering the at least one material layer to the layer of glazing material with an adhesive material.

26. The method of claim 24, further comprising configuring the plurality of HOEs to redirect sunlight along at least one axis from an angle outside a defined angle of acceptance to a new angle within the defined angle of acceptance.
